(19) United States
(12) Patent Application Publication
(10) Pub. No.: US 2026/0334113 A1
(43) Pub. Date: Oct. 22, 2026

(54) Method for Preparing a Freestanding Hafnium Zirconium Oxide Thin Film

(71) Applicant: NATIONAL CHENG KUNG UNIVERSITY, Tainan City (TW)

(72) Inventors: JAN-CHI YANG, Tainan City (TW); Bo-Cai Chen, Pingtung County (TW)

(21) Appl. No.: 19/420,821

(22) Filed: Dec. 16, 2025

(30) Foreign Application Priority Data
Apr. 16, 2025 (TW) 114114360

(51) Int. Cl. H10P 14/692; C23C 14/00; C23C 14/08; C23C 14/28; C30B 23/02; C30B 23/06; C30B 29/22; H10P 14/60

(52) U.S. Cl. CPC H10P 14/69397; C23C 14/0005; C23C 14/083; C23C 14/28; C30B 23/025; C30B 23/066; C30B 29/22; H10P 14/6349; H10P 14/69392; H10P 14/69395

(57) ABSTRACT

The present invention relates to a method for preparing a freestanding hafnium zirconium oxide thin film, and more particularly to a method comprising growing an oxide single-crystal layer on a silicon wafer substrate, subsequently growing a single-crystal sacrificial layer and a hafnium zirconium oxide film on said oxide single-crystal layer, removing the single-crystal sacrificial layer, and then peeling the hafnium zirconium oxide film from the oxide single-crystal layer to obtain a freestanding hafnium zirconium oxide thin film.

### CROSS REFERENCE TO RELATED APPLICATION

This application claims the benefits of Taiwan application Serial No. 114114360, filed on Apr. 16, 2025, the disclosures of which are incorporated by references herein in its entirety.

### TECHNICAL FIELD

The present invention relates to a method for preparing a freestanding hafnium zirconium oxide thin film, and more particularly to a method comprising growing an oxide single-crystal layer on a silicon wafer substrate, subsequently growing a single-crystal sacrificial layer and a hafnium zirconium oxide film on said oxide single-crystal layer, removing the single-crystal sacrificial layer, and then peeling the hafnium zirconium oxide film from the oxide single-crystal layer to obtain a freestanding hafnium zirconium oxide thin film.

### BACKGROUND

Since the advent of the first working integrated circuits, the miniaturization of transistors and the progress in their packing density have been remarkable. Silicon-based complementary metal-oxide-semiconductor (CMOS) technology now enables the integration of more than one billion transistors on a wafer. However, the dramatic reduction in device size also brings significant challenges, such as heat dissipation and mobility degradation. Two-dimensional (2D) semiconductors, with their atomically thin nature, enable unprecedented excellent gate controllability in transistor architectures, and therefore have attracted widespread attention as potential channel materials for next-generation electronics.

However, transistor miniaturization has enabled billions of transistors to be integrated on a chip, but it also brings thermal and mobility issues. Two-dimensional (2D) semiconductors offer a promising solution for achieving superior gate control due to their ultrathin nature. However, the lack of insulators suitable for integration into fully scalable 2D process flows limits their practical applications.

In silicon technology, the deposition of high-k dielectric materials such as Al₂O₃ and HfO₂ onto semiconductors by atomic layer deposition (ALD) is well established. However, challenges remain when applying ALD to 2D semiconductors, including the properties of amorphous dielectrics and imperfect 2D interfaces. Using thin polymers or molecules as buffers may preserve the 2D structure but at the expense of stability and dielectric constant. While van der Waals (vdW) insulators and ionic crystals such as hBN and mica have been explored in 2D transistors to improve insulator-channel interfaces and reduce trap states, compatibility challenges with silicon processing remain unsolved.

### SUMMARY

The main objective of the present invention is to provide a method for preparing a freestanding hafnium zirconium oxide (HZO) thin film, utilizing Zr-doped (HfO₂-based high-κ oxides) [Hf_{0·5}Zr_{0·5}O₂ (HZO)] to achieve ferroelectric transitions. This highlights strategic advantages in device miniaturization and compatibility with CMOS technology.

The present invention further aims to provide a method for preparing a freestanding hafnium zirconium oxide (HZO) thin film, wherein the synthesis of the resulting freestanding oxide membranes creates a viable path for integrating high-k HZO with two-dimensional (2D) semiconductors, thereby enabling superior interfaces that overcome current gate control limitations.

Another objective of the present invention is to provide a method for preparing a freestanding hafnium zirconium oxide thin film, in which a silicon wafer substrate is employed because its size is larger than that of the oxide single-crystal layer used in prior arts, thereby enabling mass production.

A method for preparing a freestanding hafnium zirconium oxide thin film, which comprises the steps of:
(SA) providing a silicon wafer substrate;
(SB) growing an oxide single-crystal layer on the silicon wafer substrate;
(SC) heating the silicon wafer substrate and the oxide single-crystal layer in a pulsed laser deposition (PLD) system in order to epitaxially grow a single-crystal lanthanum strontium manganite (LSMO) sacrificial layer on the oxide single-crystal layer;
(SD) growing a polycrystalline hafnium zirconium oxide (HZO) thin film on the single-crystal lanthanum strontium manganite (LSMO) sacrificial layer;
(SE) removing the single-crystal lanthanum strontium manganite (LSMO) sacrificial layer, thereby separating the polycrystalline hafnium zirconium oxide (HZO) thin film; and
(SF) transferring a resulting freestanding hafnium zirconium oxide thin film onto a target substrate.

Preferably, the oxide single crystal layer of the step (SB) has a (001) crystal orientation.

Preferably, epitaxially growing the single-crystal lanthanum strontium manganite (LSMO) sacrificial layer on the oxide single-crystal layer in the step (SC) is under the conditions of 600 to 750° C. of a temperature range, 150 mTorr of a pressure, a KrF excimer laser (wavelength 248 nm) of a laser source, 200 mJ of a laser energy, 10 Hz of a repetition rate.

Preferably, growing the polycrystalline hafnium zirconium oxide (HZO) thin film with 20 nm on the single-crystal lanthanum strontium manganite (LSMO) sacrificial layer in the step (SD) is under conditions of 600 to 750° C. of a temperature range, 150 mTorr of a pressure, a KrF excimer laser (wavelength 248 nm) of a laser source, 200 mJ of a laser energy, 10 Hz of a repetition rate.

Preferably, the step (SE) further comprises the steps of:
(SE1) attaching a polydimethylsiloxane (PDMS) layer on a top of the polycrystalline hafnium zirconium oxide (HZO) thin film;
(SE2) immersing a structure comprising the silicon wafer substrate, the oxide single-crystal layer, the single-crystal lanthanum strontium manganite (LSMO) sacrificial layer and the polycrystalline hafnium zirconium oxide (HZO) thin film in a hydrochloric acid aqueous solution, the polydimethylsiloxane (PDMS) layer floating on a surface of the hydrochloric acid aqueous solution;
(SE3) removing the single-crystal lanthanum strontium manganite (LSMO) sacrificial layer, so that the polycrystalline hafnium zirconium oxide (HZO) thin film is separated from the oxide single-crystal layer and the silicon wafer substrate, the polydimethylsiloxane (PDMS) layer floating on the surface of the hydrochloric acid aqueous solution; and
(SE4) applying heat to lose adhesiveness of the polydimethylsiloxane (PDMS) layer, so that the polydimethylsiloxane (PDMS) layer is separated from the polycrystalline hafnium zirconium oxide (HZO) thin film.

Preferably, the step (SE) further comprises the steps of:
(SE1′) immersing a structure comprising the silicon wafer substrate, the oxide single-crystal layer, the single-crystal lanthanum strontium manganite (LSMO) sacrificial layer, and the polycrystalline hafnium zirconium oxide (HZO) thin film in a hydrochloric acid aqueous solution;
(SE2′) removing the single-crystal lanthanum strontium manganite (LSMO) sacrificial layer, so that the polycrystalline hafnium zirconium oxide (HZO) thin film is separated from the oxide single-crystal layer and the silicon wafer substrate; and (SE3′) taking out the polycrystalline hafnium zirconium oxide (HZO) thin film, the oxide single-crystal layer and the silicon wafer substrate from the hydrochloric acid aqueous solution, and drying to remove moisture, and then immersing in deionized water, using buoyancy of the deionized water to float the polycrystalline hafnium zirconium oxide (HZO) thin film on a surface of the deionized water, thereby separating the oxide single-crystal layer and the silicon wafer substrate from the polycrystalline hafnium zirconium oxide (HZO) thin film.

Preferably, the oxide single-crystal layer of the step (SB) is selected from the group consisting of: strontium titanate (STO; SrTiO₃) thin film, yttrium orthoaluminate (YAO; YAlO₃) thin film, lanthanum aluminate (LAO; LaAlO₃) thin film, and neodymium gallium oxide; NGO; NdGaO₃) thin film.

Preferably, the target substrate of the step (SF) is a transistor.

Preferably, the single-crystal lanthanum strontium manganite (LSMO) sacrificial layer of the step (SC) is selected from the group consisting of: lanthanum calcium manganite (La₁₋ₓCaₓMnO₃; LCMO) and yttrium barium copper oxide (YBa₂Cu₃O₇).

Preferably, in the step (SE2), the single-crystal lanthanum strontium manganite sacrificial layer may be replaced with a single-crystal strontium aluminate (SAO) sacrificial layer, and the hydrochloric acid aqueous solution may be replaced with deionized water.

Preferably, in step (SE1′), the single-crystal lanthanum strontium manganite sacrificial layer may be replaced with a single-crystal strontium aluminate (SAO) sacrificial layer, and the hydrochloric acid aqueous solution may be replaced with the deionized water.

Preferably, the step (SE) further comprises the steps of:
(SE1″) coating a polymethyl methacrylate (PMMA) layer on an upper surface of the polycrystalline hafnium zirconium oxide thin film;
(SE2″) immersing a structure having the silicon wafer substrate, the oxide single-crystal (STO) layer, the single-crystal lanthanum strontium manganite (LSMO) sacrificial layer, the polycrystalline hafnium zirconium oxide (HZO) thin film, and the polymethyl methacrylate (PMMA) layer in the hydrochloric acid aqueous solution;
(SE3″) removing the single-crystal lanthanum strontium manganite (LSMO) sacrificial layer, thereby separating the polycrystalline hafnium zirconium oxide (HZO) thin film and the polymethyl methacrylate (PMMA) layer from the oxide single-crystal layer and the silicon wafer substrate;
(SE4″) taking out from the hydrochloric acid aqueous solution, drying off moisture, immersing in deionized water, and using buoyancy of the deionized water to float the polymethyl methacrylate (PMMA) layer and the polycrystalline hafnium zirconium oxide (HZO) thin film on a surface of the deionized water; and
(SE5″) immersing a structure having the polymethyl methacrylate (PMMA) layer and the polycrystalline hafnium zirconium oxide (HZO) thin film in an acetone solution to remove the polymethyl methacrylate (PMMA) layer.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 to FIG. 17 illustrate schematic block views of a plurality of preferred embodiments of the method for preparing a freestanding hafnium zirconium oxide thin film of the present invention;

FIG. 18 illustrates a schematic application view of a product of the method for preparing a freestanding hafnium zirconium oxide thin film of the present invention; and

FIG. 19 to FIG. 20 illustrate a schematic flow chart of the method for preparing a freestanding hafnium zirconium oxide thin film of the present invention.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The terms “including”, “comprising”, “having” and the like mentioned in this disclosure are all open terms; i.e., implying only “including but not limited to”.

In the description of embodiments, when terms such as “first”, “second”, “third”, “fourth” etc. are used to describe elements, they are only used to distinguish these elements from each other, but not limit order or importance of any of these elements.

In the descriptions of various embodiments, the so-called “coupling” or “connection” may refer to two or a plurality of components making physical or electrical contact directly or indirectly with each other, or refer to the mutual operation or action of two or a plurality of elements.

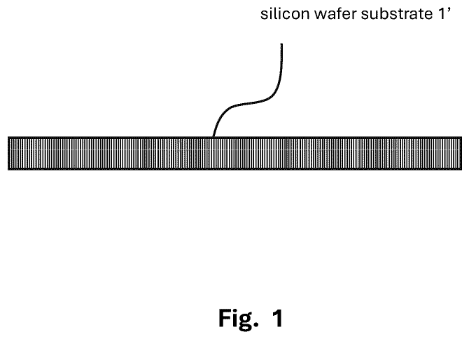

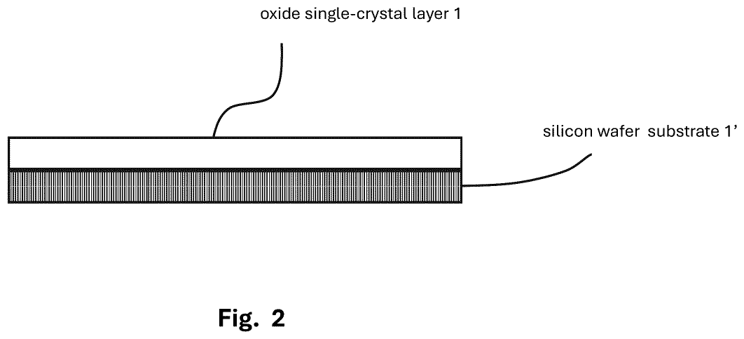

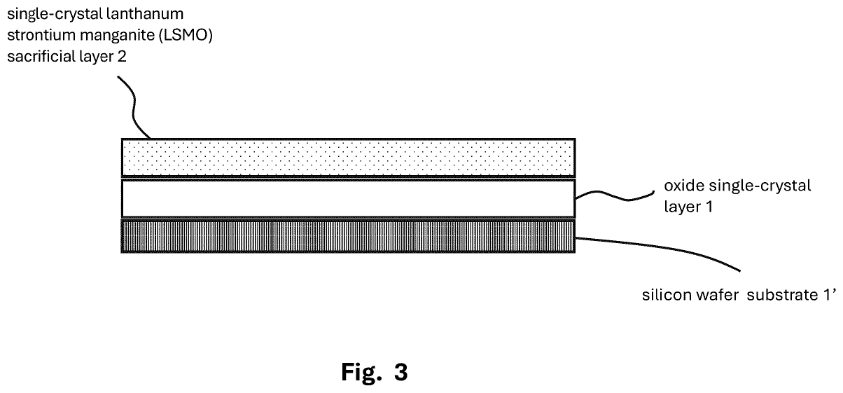

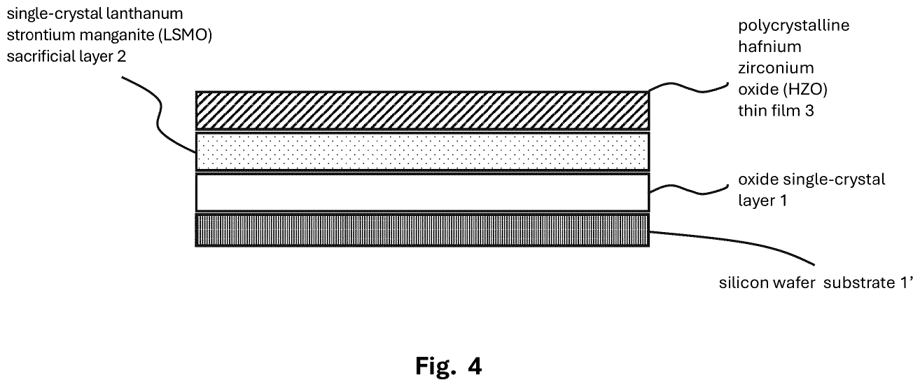

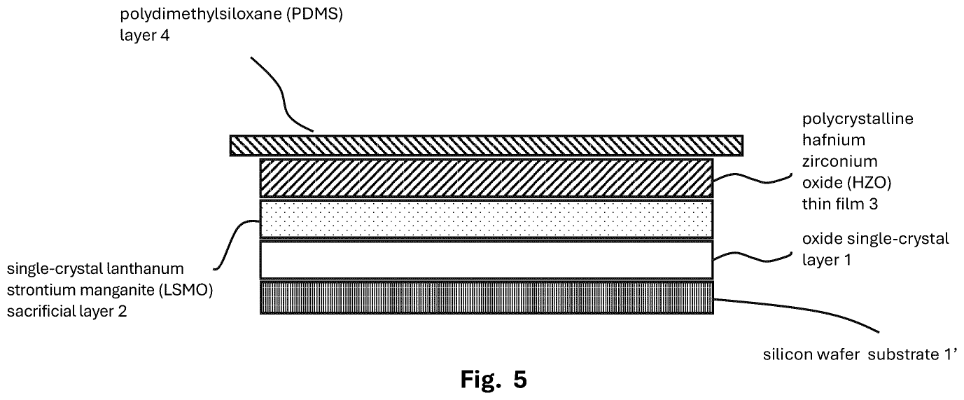

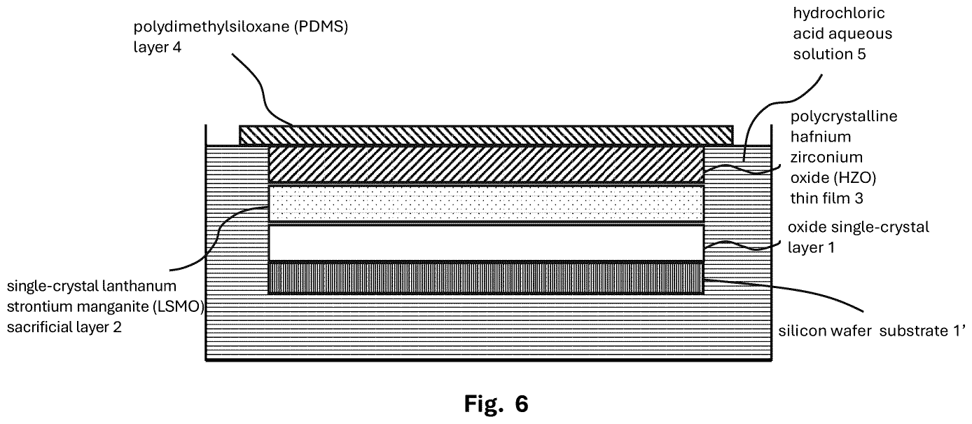

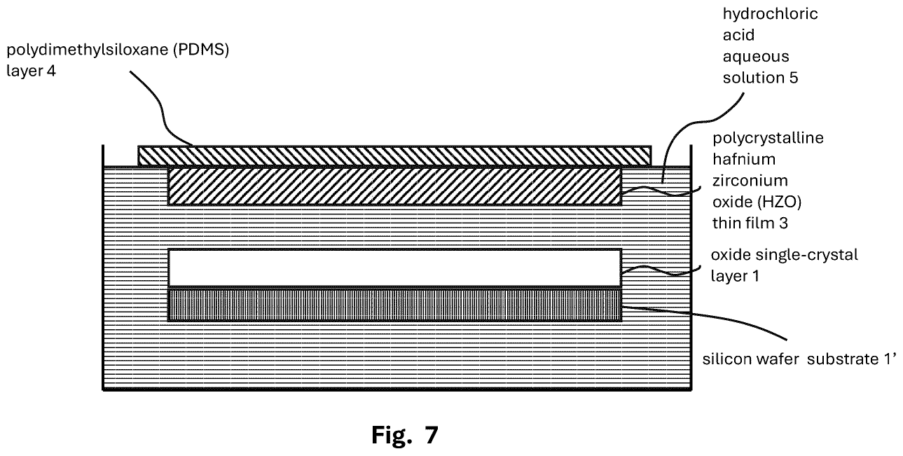

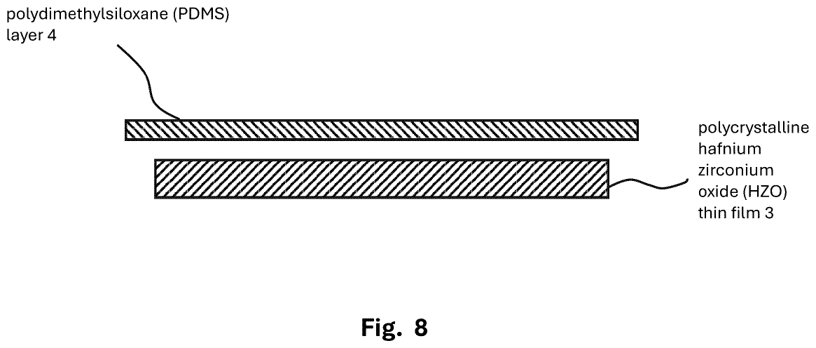

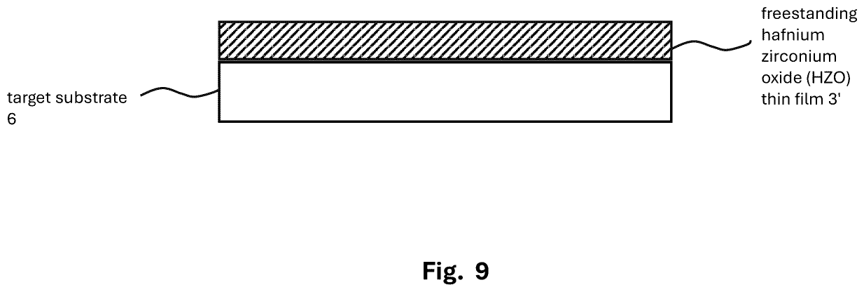

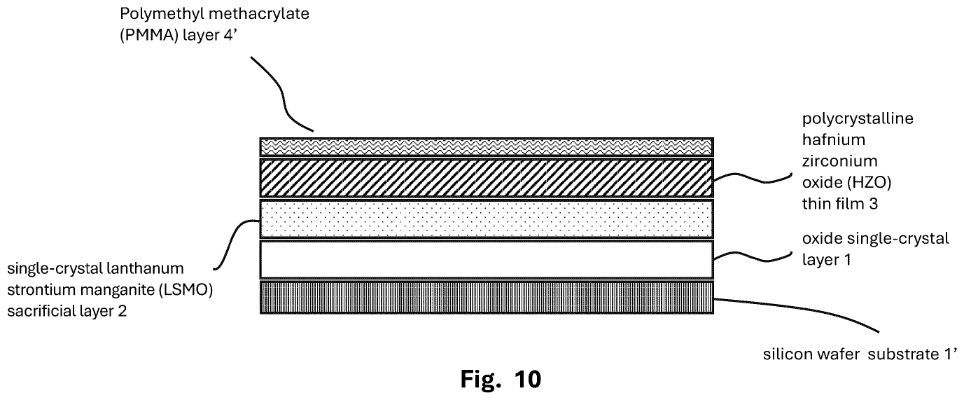

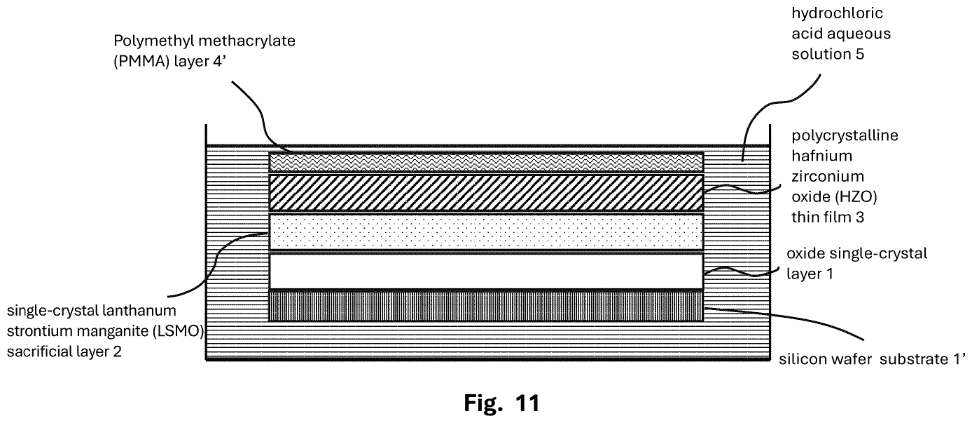

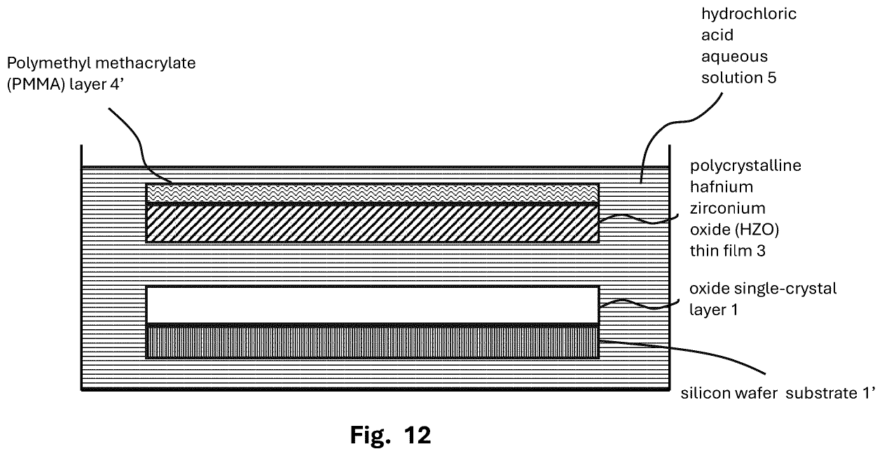

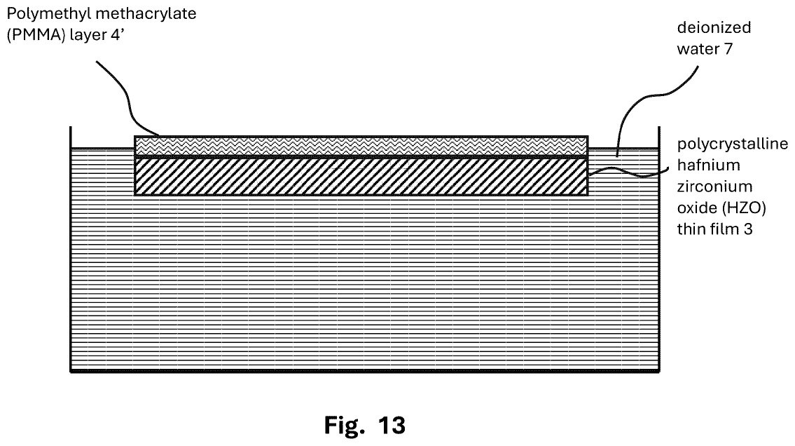

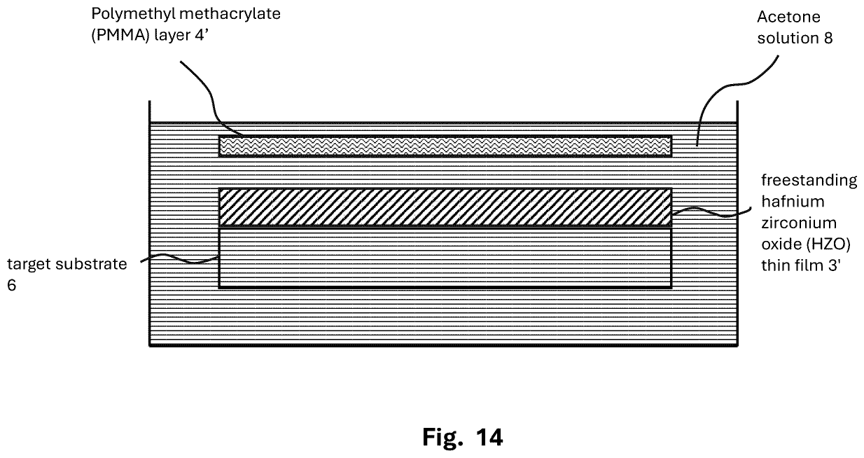

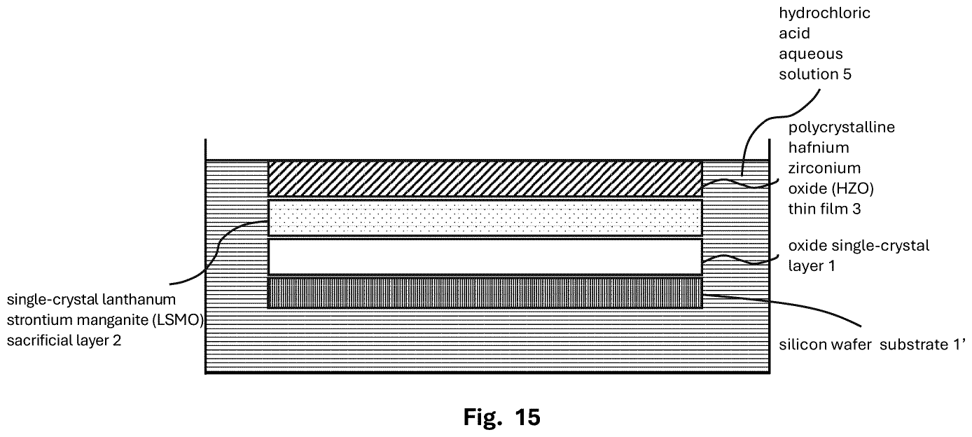

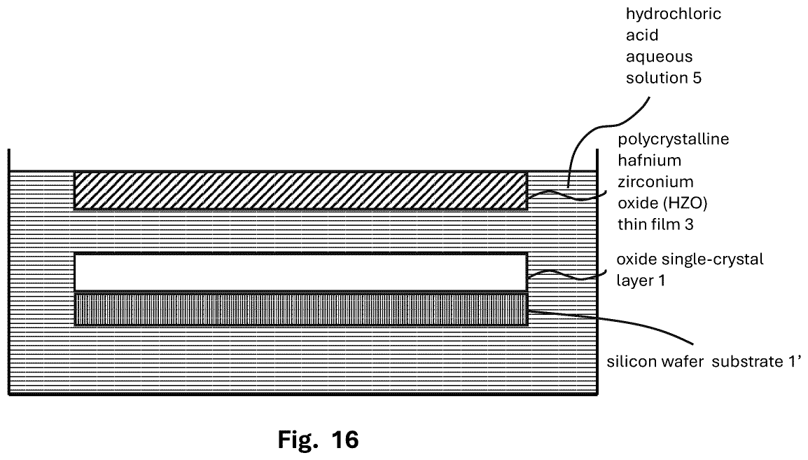

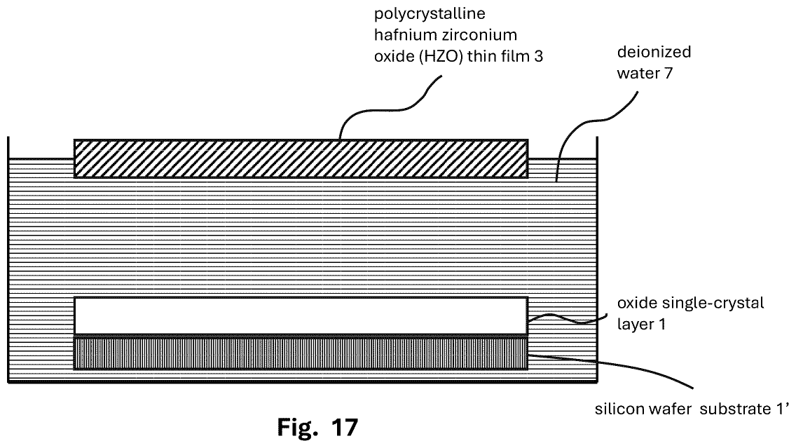

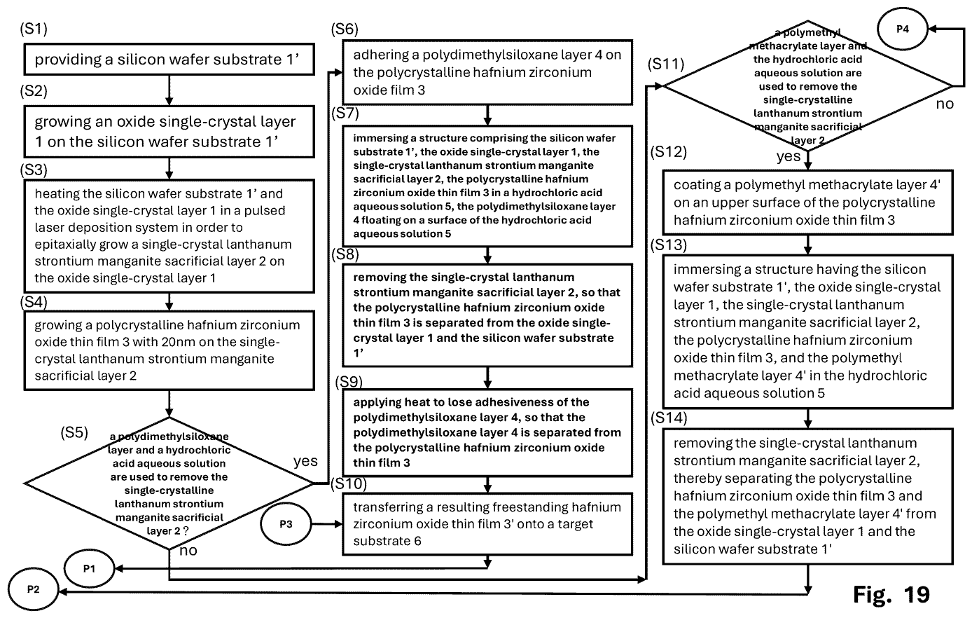

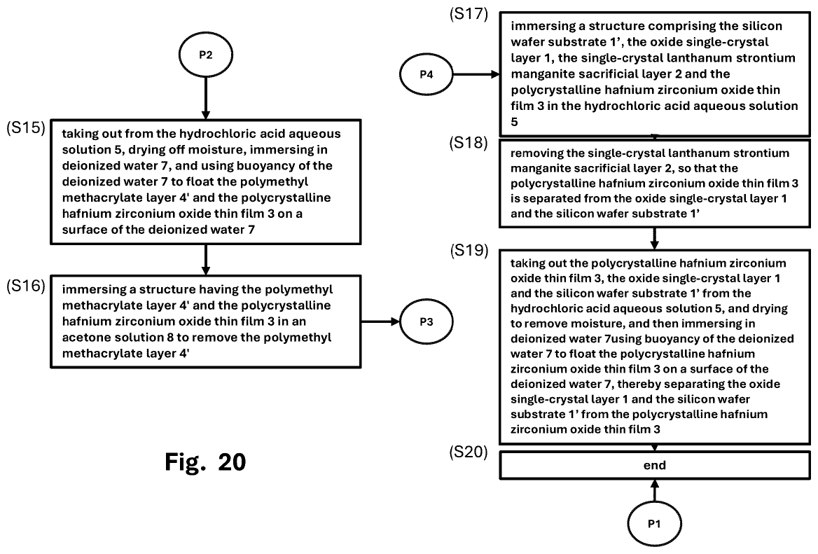

Please refer to FIG. 1 to FIG. 17 and FIG. 19 to FIG. 20, which illustrate schematic block views and a flow chart of a plurality of preferred embodiments of a method for preparing a freestanding hafnium zirconium oxide thin film of the present invention. The method has the following steps of:
(S1) providing a silicon wafer substrate 1′, please refer to FIG. 1;
(S2) growing an oxide single-crystal layer 1 on the silicon wafer substrate 1′, as shown in FIG. 2, wherein the oxide single-crystal layer 1 with the (001) crystal orientation can be one of the following: strontium titanate (STO; SrTiO₃) thin film, yttrium orthoaluminate (YAO; YAlO₃) thin film, lanthanum aluminate (LAO; LaAlO₃) thin film, and neodymium gallium oxide; NGO; NdGaO₃) thin film;
(S3) heating the silicon wafer substrate 1′ and the oxide single-crystal layer 1 in a pulsed laser deposition (PLD) system in order to epitaxially grow a single-crystal lanthanum strontium manganite (LSMO) sacrificial layer 2 on the oxide single-crystal layer 1 under the conditions of 600 to 750° C. of a temperature range, 150 mTorr of a pressure, a KrF excimer laser (248 nm of a wavelength) of a laser source, 200 mJ of a laser energy, and 10 Hz of a repetition rate, as shown in FIG. 3, wherein the single-crystal lanthanum strontium manganite (LSMO) sacrificial layer 2 can be one of the following: lanthanum calcium manganite (La₁₋ₓCaₓMnO₃; LCMO) and yttrium barium copper oxide (YBa₂Cu₃O₇);
(S4) growing a polycrystalline hafnium zirconium oxide (HZO) thin film 3 with 20 nm on the single-crystal lanthanum strontium manganite (LSMO) sacrificial layer 2 under the conditions of 600 to 750° C. of a temperature range, 150 mTorr of a pressure, a KrF excimer laser (248 nm of a wavelength) of a laser source, 200 mJ of a laser energy, 10 Hz of a repetition rate, as shown in FIG. 4;
(S5) determining whether a polydimethylsiloxane (PDMS) layer and a hydrochloric acid aqueous solution are used to remove the single-crystalline lanthanum strontium manganite (LSMO) sacrificial layer 2, if yes, going to step (S6), otherwise, going to step (S11);
(S6) adhering a polydimethylsiloxane (PDMS) layer 4 on the polycrystalline hafnium zirconium oxide (HZO) film 3, as shown in FIG. 5;
(S7) immersing a structure comprising the silicon wafer substrate 1′, the oxide single-crystal layer 1, the single-crystal lanthanum strontium manganite (LSMO) sacrificial layer 2, the polycrystalline hafnium zirconium oxide (HZO) thin film 3 in a hydrochloric acid aqueous solution 5, the polydimethylsiloxane (PDMS) layer 4 floating on a surface of the hydrochloric acid aqueous solution 5, as shown in FIG. 6;
(S8) removing the single-crystal lanthanum strontium manganite (LSMO) sacrificial layer 2, so that the polycrystalline hafnium zirconium oxide (HZO) thin film 3 is separated from the oxide single-crystal layer 1 and the silicon wafer substrate 1′, the polydimethylsiloxane (PDMS) layer 4 floating on a surface of the hydrochloric acid aqueous solution 5, as shown in FIG. 7;
(S9) applying heat to lose adhesiveness of the polydimethylsiloxane (PDMS) layer 4, so that the polydimethylsiloxane (PDMS) layer 4 is separated from the polycrystalline hafnium zirconium oxide (HZO) thin film 3, as shown in FIG. 8;
(S10) transferring a resulting freestanding hafnium zirconium oxide (HZO) thin film 3′ onto a target substrate 6, as shown in FIG. 9, and going to step (S20)
(S11) determining whether a polymethyl methacrylate (PMMA) layer and the hydrochloric acid aqueous solution are used to remove the single-crystalline lanthanum strontium manganite (LSMO) sacrificial layer 2, if yes, going to step (S12), otherwise, going to step (S17);
(S12) coating a polymethyl methacrylate (PMMA) layer 4′ on an upper surface of the polycrystalline hafnium zirconium oxide thin film 3, as shown in FIG. 10;
(S13) immersing a structure having the silicon wafer substrate 1′, the oxide single-crystal (STO) layer 1, the single-crystal lanthanum strontium manganite (LSMO) sacrificial layer 2, the polycrystalline hafnium zirconium oxide (HZO) thin film 3, and the polymethyl methacrylate (PMMA) layer 4′ in the hydrochloric acid aqueous solution 5, as shown in FIG. 11;
(S14) removing the single-crystal lanthanum strontium manganite (LSMO) sacrificial layer 2, thereby separating the polycrystalline hafnium zirconium oxide (HZO) thin film 3 and the polymethyl methacrylate (PMMA) layer 4′ from the oxide single-crystal layer 1 and the silicon wafer substrate 1′, as shown in FIG. 12;
(S15) taking out from the hydrochloric acid aqueous solution 5, drying off moisture, immersing in deionized water 7, and using buoyancy of the deionized water 7 to float the polymethyl methacrylate (PMMA) layer 4′ and the polycrystalline hafnium zirconium oxide (HZO) thin film 3 on a surface of the deionized water 7, as shown in FIG. 13;
(S16) immersing a structure having the polymethyl methacrylate (PMMA) layer 4′ and the polycrystalline hafnium zirconium oxide (HZO) thin film 3 in an acetone solution 8 to remove the polymethyl methacrylate (PMMA) layer 4′, as shown in FIG. 14, and going to step (S10);
(S17) immersing a structure comprising the silicon wafer substrate 1′, the oxide single-crystal layer 1, the single-crystal lanthanum strontium manganite (LSMO) sacrificial layer 2 and the polycrystalline hafnium zirconium oxide (HZO) thin film 3 in the hydrochloric acid aqueous solution 5, as shown in FIG. 15;
(S18) removing the single-crystal lanthanum strontium manganite (LSMO) sacrificial layer 2, so that the polycrystalline hafnium zirconium oxide (HZO) thin film 3 is separated from the oxide single-crystal layer 1 and the silicon wafer substrate 1′, as shown in FIG. 16;
(S19) taking out the polycrystalline hafnium zirconium oxide (HZO) thin film 3, the oxide single-crystal layer 1 and the silicon wafer substrate 1′ from the hydrochloric acid aqueous solution 5, and drying to remove moisture, and then immersing in the deionized water 7, using buoyancy of the deionized water 7 to float the polycrystalline hafnium zirconium oxide (HZO) thin film 3 on a surface of the deionized water 7, thereby separating the oxide single-crystal layer 1 and the silicon wafer substrate 1′ from the polycrystalline hafnium zirconium oxide (HZO) thin film 3, as shown in FIG. 17, and going to step (S10); and
(S20) end.

According to the steps described above, there are three methods for forming the freestanding hafnium zirconium oxide (HZO) thin film 3′. The first embodiment involves steps (S1) to (S4), the second embodiment involves steps (S1) to (S4) and steps (S12) to (S16), and the third embodiment involves steps (S1) to (S4) and steps (S17) to (S19). Further, the target substrate 6 onto which the freestanding hafnium zirconium oxide (HZO) thin film 3′ is transferred may be a transistor, any other specific substrate material, a device, or the like.

The aforementioned single-crystal lanthanum strontium manganite (LSMO) sacrificial layer may be replaced with a single-crystal strontium aluminate (SAO) sacrificial layer. The hydrochloric acid aqueous solution can be replaced with deionized water, and the hydrochloric acid aqueous solution is a mixed solution of water, hydrochloric acid, and potassium iodide (KI). Furthermore, in actual operation, the order of step (S9) to step (S10), and the order of step (S19) to step (S10), can be interchanged.

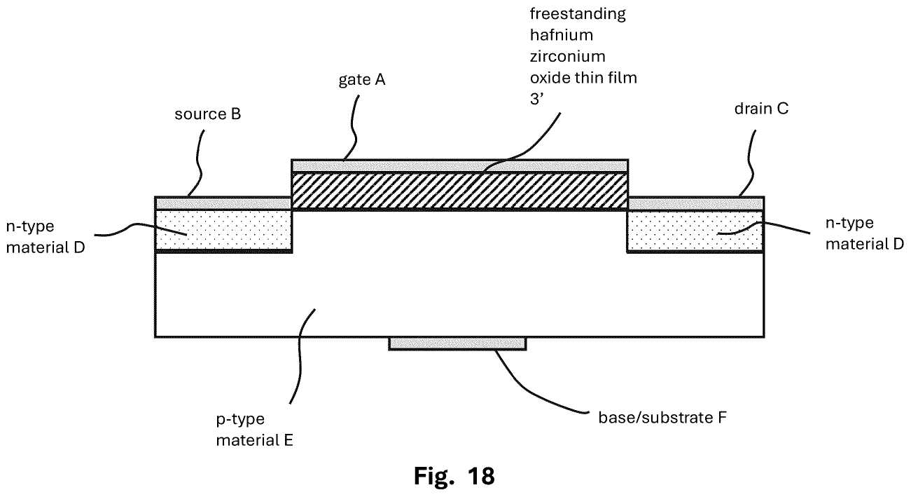

With reference to FIG. 18, which illustrates an application schematic view of a product obtained by the method for preparing a freestanding hafnium zirconium oxide (HZO) thin film of the present invention. As shown in FIG. 13, which is a field effect transistor (FET), and it can be associated with applications such as ferroelectric memory, advanced CMOS devices, or two-dimensional material-based FETs. In particular, the structure includes a ferroelectric gate dielectric layer (HZO thin film), with n-type source and drain regions and a p-type substrate, constituting an n-channel MOSFET (n-MOS) architecture. The functions and relationships of each part are described as following:

| Component | | Relationship and |
|---|---|---|
| Name | Description and Function | Connection |
| Gate A | Electrode for applying | Located at the central top |
| | control voltage; | of the device; in contact |
| | controlling whether the | with the freestanding |
| | conductivity of the | hafnium zirconium oxide |
| | channel is turned on or off | thin film 3′ |
| Freestanding | Polycrystalline HfZrOₓ; a | Positioned between Gate |
| Hafnium | | |
| Zirconium | ferroelectric material used | A and the channel region |
| Oxide Thin | as the gate dielectric | (p-type material E) |
| Film 3′ | layer, with memory and | |
| | control functionality | |
| Source B | Current injection terminal | In contact with n-type |
| | | material D; located on the |
| | | left side |
| Drain C | Current collection | In contact with n-type |
| | terminal | material D; located on the |
| | | right side |
| n-type | Conductive region | Distributed beneath |
| Material D | forming the contact | Source B and Drain C; |
| | material of source and | embedded in pn junctions |
| | drain | with p-type material E |
| p-type | Substrate body material | Distributed across the |
| Material E | forming the channel | entire bottom area; |
| | region | supporting the channel |
| | | and elements |
| Base/ | Structural support of the | Supporting the entire |
| Substrate F | entire device, may also | device and located at the |
| | serve as a back-gate | bottom layer; can function |
| | | as a back-gate when a |
| | | voltage is applied |

The structure described above, assuming it is an n-MOS, operates based on the following principles:
(1) When a positive voltage is applied to gate A, the freestanding hafnium zirconium oxide (HZO) thin film 3′ senses the electric field and alters the surface electrical properties of the underlying p-type material E;
(2) If an inversion layer (n-type channel) is formed, a conductive path is established between the source B and the drain C;
(3) Current can then flow from the source B to the drain C, and this process is controlled by the gate A; and
(4) The ferroelectricity of the freestanding hafnium zirconium oxide (HZO) thin film 3′ may also provide non-volatile memory functionality, such as in FeFET applications.

More, the product of the method for preparing a freestanding hafnium zirconium oxide thin film of the present invention is a freestanding HZO film. Due to the high dielectric constant (approximately 19.5) and ultra-low leakage current (<2.6×10⁻⁶ A/cm²@1 MV/cm) of its two main advantages, it offers excellent gate control in 2D semiconductors (e.g., MoS₂) and enhances element stability and energy efficiency. The product can be applied in the following areas:
(1) FeFET (Ferroelectric FET): Utilizing the ferroelectric properties of HZO (Hf_{0·5}Zr_{0·5}O₂) to realize low-power memory devices.
(2) Advanced FinFET/GAA structures: When integrated with nanowires or two-dimensional materials, it enables high drive current capability and short-channel control.

In summary, the method for preparing a freestanding hafnium zirconium oxide (HZO) thin film presented in this invention offers the following advantages:
1. The high crystallinity of the HZO thin film epitaxially grown by pulsed laser deposition (PLD) provides superior electrical performance and enhanced competitiveness.
2. By employing a transfer process to integrate the film with target substrates or transistors, temperature constraints typically associated with HZO processing can be eliminated.
3. For those transistors, which tops hardly grow thin films, such as two-dimensional materials, the transferred HZO gate is a suitable and effective choice.
4. A silicon wafer substrate is employed because the oxide single-crystal layer used in prior arts has a limitation in size, whereas the silicon wafer substrate is much larger in size, thereby enabling mass production.

What is claimed is:

1. A method for preparing a freestanding hafnium zirconium oxide thin film, comprising the steps of:
(SA) providing a silicon wafer substrate;
(SB) growing an oxide single-crystal layer on the silicon wafer substrate;
(SC) heating the silicon wafer substrate and the oxide single-crystal layer in a pulsed laser deposition (PLD) system in order to epitaxially grow a single-crystal lanthanum strontium manganite (LSMO) sacrificial layer on the oxide single-crystal layer;
(SD) growing a polycrystalline hafnium zirconium oxide (HZO) thin film on the single-crystal lanthanum strontium manganite (LSMO) sacrificial layer;
(SE) removing the single-crystal lanthanum strontium manganite (LSMO) sacrificial layer, thereby separating the polycrystalline hafnium zirconium oxide (HZO) thin film; and
(SF) transferring a resulting freestanding hafnium zirconium oxide thin film onto a target substrate.

2. The method for preparing the freestanding hafnium zirconium oxide thin film according to claim 1, wherein the oxide single crystal layer of the step (SB) has a (001) crystal orientation.

3. The method for preparing the freestanding hafnium zirconium oxide thin film according to claim 1, wherein epitaxially growing the single-crystal lanthanum strontium manganite (LSMO) sacrificial layer on the oxide single-crystal layer in the step (SC) is under conditions of 600 to 750° C. of a temperature range, 150 mTorr of a pressure, a KrF excimer laser (wavelength 248 nm) of a laser source, 200 mJ of a laser energy, 10 Hz of a repetition rate.

4. The method for preparing the freestanding hafnium zirconium oxide thin film according to claim 1, growing the polycrystalline hafnium zirconium oxide (HZO) thin film with 20 nm on the single-crystal lanthanum strontium manganite (LSMO) sacrificial layer in the step (SD) is under conditions of 600 to 750° C. of a temperature range, 150 mTorr of a pressure, a KrF excimer laser (wavelength 248 nm) of a laser source, 200 mJ of a laser energy, 10 Hz of a repetition rate.

5. The method for preparing the freestanding hafnium zirconium oxide thin film according to claim 1, wherein the step (SE) further comprises the steps of:
(SE1) attaching a polydimethylsiloxane (PDMS) layer on a top of the polycrystalline hafnium zirconium oxide (HZO) thin film;
(SE2) immersing a structure comprising the silicon wafer substrate, the oxide single-crystal layer, the single-crystal lanthanum strontium manganite (LSMO) sacrificial layer and the polycrystalline hafnium zirconium oxide (HZO) thin film in a hydrochloric acid aqueous solution, the polydimethylsiloxane (PDMS) layer floating on a surface of the hydrochloric acid aqueous solution;
(SE3) removing the single-crystal lanthanum strontium manganite (LSMO) sacrificial layer, so that the polycrystalline hafnium zirconium oxide (HZO) thin film is separated from the oxide single-crystal layer and the silicon wafer substrate, the polydimethylsiloxane (PDMS) layer floating on the surface of the hydrochloric acid aqueous solution; and
(SE4) applying heat to lose adhesiveness of the polydimethylsiloxane (PDMS) layer, so that the polydimethylsiloxane (PDMS) layer is separated from the polycrystalline hafnium zirconium oxide (HZO) thin film.

6. The method for preparing the freestanding hafnium zirconium oxide thin film according to claim 1, wherein the step (SE) further comprises the steps of:
(SE1′) immersing a structure comprising the silicon wafer substrate, the oxide single-crystal layer, the single-crystal lanthanum strontium manganite (LSMO) sacrificial layer, and the polycrystalline hafnium zirconium oxide (HZO) thin film in a hydrochloric acid aqueous solution;
(SE2′) removing the single-crystal lanthanum strontium manganite (LSMO) sacrificial layer, so that the polycrystalline hafnium zirconium oxide (HZO) thin film is separated from the oxide single-crystal layer and the silicon wafer substrate; and
(SE3′) taking out the polycrystalline hafnium zirconium oxide (HZO) thin film, the oxide single-crystal layer and the silicon wafer substrate from the hydrochloric acid aqueous solution, and drying to remove moisture, and then immersing in deionized water, using buoyancy of the deionized water to float the polycrystalline hafnium zirconium oxide (HZO) thin film on a surface of the deionized water, thereby separating the oxide single-crystal layer and the silicon wafer substrate from the polycrystalline hafnium zirconium oxide (HZO) thin film.

7. The method for preparing the freestanding hafnium zirconium oxide thin film according to claim 1, wherein the oxide single-crystal layer of the step (SB) is selected from the group consisting of: strontium titanate (STO; SrTiO₃) thin film, yttrium orthoaluminate (YAO; YAlO₃) thin film, lanthanum aluminate (LAO; LaAlO₃) thin film, and neodymium gallium oxide; NGO; NdGaO₃) thin film.

8. The method for preparing the freestanding hafnium zirconium oxide thin film according to claim 1, wherein the target substrate of the step (SF) is a transistor.

9. The method for preparing the freestanding hafnium zirconium oxide thin film according to claim 1, wherein the single-crystal lanthanum strontium manganite (LSMO) sacrificial layer of the step (SC) is selected from the group consisting of: lanthanum calcium manganite (La₁₋ₓCaₓMnO₃; LCMO) and yttrium barium copper oxide (YBa₂Cu₃O₇).

10. The method for preparing the freestanding hafnium zirconium oxide thin film according to claim 5, wherein in the step (SE2), the single-crystal lanthanum strontium manganite sacrificial layer may be replaced with a single-crystal strontium aluminate (SAO) sacrificial layer, and the hydrochloric acid aqueous solution may be replaced with deionized water.

11. The method for preparing the freestanding hafnium zirconium oxide thin film according to claim 6, wherein in step (SE1′), the single-crystal lanthanum strontium manganite sacrificial layer may be replaced with a single-crystal strontium aluminate (SAO) sacrificial layer, and the hydrochloric acid aqueous solution may be replaced with the deionized water.

12. The method for preparing the freestanding hafnium zirconium oxide thin film according to claim 1, wherein the step (SE) comprises the steps of:
(SE1″) coating a polymethyl methacrylate (PMMA) layer on an upper surface of the polycrystalline hafnium zirconium oxide thin film;
(SE2″) immersing a structure having the silicon wafer substrate, the oxide single-crystal (STO) layer, the single-crystal lanthanum strontium manganite (LSMO) sacrificial layer, the polycrystalline hafnium zirconium oxide (HZO) thin film, and the polymethyl methacrylate (PMMA) layer in the hydrochloric acid aqueous solution;
(SE3″) removing the single-crystal lanthanum strontium manganite (LSMO) sacrificial layer, thereby separating the polycrystalline hafnium zirconium oxide (HZO) thin film and the polymethyl methacrylate (PMMA) layer from the oxide single-crystal layer and the silicon wafer substrate;
(SE4″) taking out from the hydrochloric acid aqueous solution, drying off moisture, immersing in deionized water, and using buoyancy of the deionized water to float the polymethyl methacrylate (PMMA) layer and the polycrystalline hafnium zirconium oxide (HZO) thin film on a surface of the deionized water; and
(SE5″) immersing a structure having the polymethyl methacrylate (PMMA) layer and the polycrystalline hafnium zirconium oxide (HZO) thin film in an acetone solution to remove the polymethyl methacrylate (PMMA) layer.
